(19) United States
(12) Patent Application Publication
(10) Pub. No.: US 2026/0275513 A1
(43) Pub. Date: Sep. 17, 2026

(54) CHAMBER CLEANING FOR SUBSTRATE PROCESSING SYSTEMS

(71) Applicant: LAM RESEARCH CORPORATION, Fremont, CA (US)

(72) Inventors: Dong WANG, Sherwood, OR (US); Hu KANG, Tualatin, OR (US); Huifeng ZHENG, Beaverton, OR (US); Defu LIANG, Wilsonville, OR (US); Joseph Lindsey WOMACK, Tigard, OR (US); Ming LI, Fremont, CA (US); Xin MENG, Ontario (CA); Rohit ODE, Portland, OR (US)

(21) Appl. No.: 19/166,761

(22) PCT Filed: Mar. 7, 2024
(86) PCT No.: PCT/US2024/018768

§ 371 Date: Sep. 18, 2025

Related U.S. Application Data
(60) Provisional application No. 63/453,740, filed on Mar. 21, 2023.

(51) Int. Cl. C23C 16/44; H01J 37/32

(52) U.S. Cl. CPC C23C 16/4405; H01J 37/32862

(57) ABSTRACT

A substrate processing system includes a process chamber, processing stations, and a hub. The processing stations are disposed in the process chamber. Each of the processing stations includes a respective substrate support. The hub is disposed between the processing stations. The hub rotates between a first position and a second position, directs a gas to clean a first area of the process chamber when in the first position, and directs the gas to clean a second area of the process chamber when in the second position.

### CROSS-REFERENCE TO RELATED APPLICATIONS

This application claims the benefit of U.S. Provisional Application No. 63/453,740, filed on Mar. 21, 2023. The entire disclosure of the application referenced above is incorporated herein by reference.

### FIELD

The present disclosure relates to cleaning substrate process chambers, and more particularly, to cleaning chambers post carbon film deposition processes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to perform treatments such as deposition and etching of film on substrates such as semiconductor wafers. For example, deposition may be performed to deposit conductive film, dielectric film, or other types of film using chemical vapor deposition (CVD), plasma enhanced CVD (PECVD), atomic layer deposition (ALD), plasma enhance ALD (PEALD), and/or other deposition processes. During deposition, the substrate is arranged on a substrate support (e.g., a pedestal) and one or more precursor gases may be supplied to a process chamber using a gas distribution device (e.g., a showerhead) during one or more process steps. In a PECVD or PEALD process, plasma is used to activate chemical reactions within the process chamber during deposition.

### SUMMARY

A substrate processing system is disclosed and includes a process chamber, processing stations, and a hub. The processing stations are disposed in the process chamber. Each of the processing stations includes a respective substrate support. The hub is disposed between the processing stations. The hub rotates between a first position and a second position, directs a gas to clean a first area of the process chamber when in the first position, and directs the gas to clean a second area of the process chamber when in the second position.

In other features, each of the processing stations includes a respective showerhead. In other features, the hub is configured to hold substrate transfer paddles for transferring substrates between the processing stations. In other features, the gas is a remote plasma clean gas received from a remote plasma source. In other features, the gas includes O₂ plasma gas. In other features, the hub includes trenches for directing the gas at areas within the process chamber.

In other features, the substrate processing system further including at least one controller configured to perform one or more cleaning processes to remove deposits from within the process chamber. The one or more cleaning processes include directing the gas at the hub and rotating the hub between the first position and the second position.

In other features, the at least one controller is configured to deposit a carbon film layer on each of substrates held by the substrate supports, remove the substrates from the process chamber, and perform the one or more cleaning processes to remove carbon deposits within the process chamber.

In other features, the at least one controller is configured to rotate the hub to 0°, 30°, 45° and 60° positions during the one or more cleaning processes. In other features, the at least one controller is configured to rotate the hub to 2-5 different positions during the one or more cleaning processes. In other features, the at least one controller is configured to rotate the hub to 3-4 different positions during the one or more cleaning processes. In other features, the at least one controller is configured to rotate the hub to at least 3 different positions during the one or more cleaning processes.

In other features, the at least one controller is configured to perform: a first in-situ plasma clean operation; a hybrid clean operation including performing a second in-situ plasma clean operation concurrently with performing a first remote plasma clean operation; and a second remote plasma clean operation.

In other features, the at least one controller is configured to maintain the hub in a first position while performing the first in-situ plasma clean operation, the hybrid clean operation, and the second remote plasma clean operation. In other features, the at least one controller is configured to, during the hybrid clean operation, decrease temperatures of the substrate supports.

In other features, the at least one controller is configured to i) perform an in-situ plasma clean operation, ii) increase temperatures of the substrate supports and showerheads of the processing stations for the in-situ plasma clean operation, and iii) reduce the temperatures of the substrate supports and the showerheads subsequent to performing the in-situ plasma clean operation.

In other features, the at least one controller is configured to: deposit an undercoat layer on each of the substrate supports; move substrates onto the substrate supports; deposit a carbon film layer on each of the substrates held by the substrate supports; remove the substrates; and perform a remote plasma clean operation to remove the undercoat layer from each of the substrate supports.

In other features, the remote plasma clean operation to remove the undercoat layer includes introducing nitrogen fluoride gas into the process chamber and directing the nitrogen fluoride gas at a center of the hub. In other features, the at least one controller is configured to maintain the hub at different angular positions for different periods of time during each of the one or more cleaning processes.

In other features, the at least one controller is configured to: perform a first remote plasma clean operation while the hub is in the first position; perform a second remote plasma clean operation while the hub is in the second position; perform a third remote plasma clean operation while the hub is in a third position; perform a fourth remote plasma clean operation while the hub is in a fourth position; and perform a hybrid plasma clean operation while the hub is in a fifth position.

In other features, the at least one controller is configured to decrease temperatures of showerheads of the processing stations during the third remote plasma clean operation. In other features, the at least one controller is configured to decrease temperatures of the substrate supports and showerheads of the processing stations such that, at an end of the hybrid plasma clean operation and in preparation for performing deposition, the substrate supports are at a first temperature and the showerheads are at a second temperature.

In other features, a method for cleaning an interior of a process chamber is disclosed. The method includes: supplying a gas to the process chamber; directing the gas at a hub, the hub being located between processing stations, each processing station of the processing stations including a substrate support; maintaining the hub at a first position for a first predetermined period of time to direct the gas at a first portion of an interior of the process chamber to clean the first portion of the interior; and rotating the hub to a second position to direct the gas at a second portion of the interior to clean the second portion of the interior. In other features, the hub is configured to hold substrate transfer paddles for transferring substrates between the processing stations.

In other features, the method further includes: depositing a carbon film layer on each substrate held by the substrate supports; and removing the substrates from the process chamber. The directing of the gas at the first portion and the second portion removes carbon deposits within the process chamber, which were deposited during the deposition of the carbon film layer.

In other features, the first position is a 0° position and other cleaning positions of the hub include a 30° position, a 45° position and a 60° position. In other features, the method includes rotating the hub to a total of 2-5 different positions including the first position and other positions during a cleaning process of the interior of the process chamber. In other features, the method includes rotating the hub to a total of 3-4 different positions including the first position and other positions during a cleaning process of the interior of the process chamber. In other features, the method includes rotating the hub to at least three different positions including the first position and other positions during a cleaning process of the interior of the process chamber.

In other features, the gas is a remote plasma clean gas. In other features, the method further includes performing: a first in-situ plasma clean operation including supplying another gas via a showerhead of each of the processing stations; a hybrid clean operation including performing a second in-situ plasma clean operation concurrently with performing a first remote plasma clean operation. The second in-situ plasma clean operation includes supplying gas via the showerheads. The first remote plasma clean operation includes supplying the remote plasma clean gas via a remote plasma source. The method further includes performing a second remote plasma clean operation including supplying the remote plasma clean gas via the remote plasma source.

In other features, the method further includes maintaining the hub in the first position while performing the first in-situ plasma clean operation, the hybrid clean operation, and the second remote plasma clean operation. In other features, the method further includes, during the hybrid clean operation, decreasing temperatures of the substrate supports.

In other features, the method further includes: performing an in-situ plasma clean operation; increasing temperatures of the substrate supports and the showerheads for the in-situ plasma clean operation; and reducing the temperatures of the substrate supports and the showerheads subsequent to performing the in-situ plasma clean operation.

In other features, the method further includes: depositing an undercoat layer on the substrate supports; moving substrates onto the substrate supports; depositing a carbon film layer on each of substrates held by the substrate supports; removing the substrates; and performing a remote plasma clean operation to remove the undercoat layer.

In other features, the remote plasma clean operation to remove the undercoat layer includes introducing nitrogen fluoride into the process chamber. In other features, the remote plasma clean operation includes supplying and directing O₂ plasma gas at the hub. In other features, the method further includes directing the gas via trenches of the hub. In other features, the method further includes maintaining the hub at different angular positions for different periods of time during a cleaning process.

In other features, the method further includes: performing a first remote plasma clean operation while the hub is in the first position; performing a second remote plasma clean operation while the hub is in a second position; performing a third remote plasma clean operation while the hub is in a third position; performing a fourth remote plasma clean operation while the hub is in a fourth position; and performing a hybrid plasma clean operation while the hub is in a fifth position.

In other features, the method further includes decreasing temperatures of showerheads of the processing stations during the third remote plasma clean operation. In other features, the method further includes decreasing temperatures of the substrate supports and showerheads of the processing stations such that, at an end of the hybrid plasma clean operation and in preparation for performing deposition, the substrate supports are at a first temperature and the showerheads are at a second temperature.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a portion of a substrate processing system including a system controller executing a chamber clean application in accordance with the present disclosure;

FIG. 2 is a perspective view of an interior of a process chamber including a hub with directional trenches in accordance with the present disclosure;

FIG. 3 is a top view of a process chamber including a hub with directional trenches in accordance with the present disclosure;

FIG. 4A is a top view of a process chamber illustrating a hub in a first (or default) position in accordance with the present disclosure;

FIG. 4B is a top view of the process chamber of FIG. 4A illustrating the hub in a second position;

FIG. 4C is a top view of the process chamber of FIG. 4A illustrating the hub in a third position;

FIG. 5 is a functional block diagram of another portion of the substrate processing system of FIG. 1 including a temperature control system for heating and cooling substrate supports and showerheads during cleaning processes in accordance with the present disclosure;

FIG. 6 is a plot of substrate support (or pedestal) and showerhead temperatures during a partial clean process in accordance with the present disclosure;

FIG. 7 is cleaning diagram illustrating a full clean process in accordance with the present disclosure;

FIG. 8 illustrates a carbon film deposition process including a full clean process in accordance with the present disclosure; and

FIG. 9. illustrates a partial clean process in accordance with the present disclosure.

In the drawings, reference numbers may be reused to identify similar and/or identical elements.

### DETAILED DESCRIPTION

A PECVD process can include depositing an amorphous carbon film layer on a substrate. The amorphous carbon film layer is deposited at a low temperature (e.g., 250° C.) and tends to be a thick layer (e.g., 2.0 microns (u) thick). During the deposition process, carbon is deposited on substrates as well as on interior chamber elements such as interior chamber walls and chamber ribs. Due to the low temperature, deposition on remote areas of the chamber (e.g., interior surfaces of walls and corners of process chamber) more readily occurs. In addition, due to the thickness of deposition, more cleaning of the interior is needed to remove the carbon deposits on the interior chamber elements. If the interior chamber elements are not adequately cleaned, build up can occur, which can result in increased particles in the process chamber that can negatively affect substrate processing. A partial clean process is performed subsequent to depositing the amorphous carbon film layer and removal of the substrates from the process chamber. The partial clean process is implemented to remove accumulated deposits of carbon on the chamber interior elements.

Amorphous carbon film layers can be formed during fabrication of three-dimensional (3D) nano-scale components and devices to provide ashable hard masks. It can however be challenging to thoroughly and efficiently remove all carbon deposits on interior chamber elements especially in remote areas (areas furthest from a center of the chamber) post an amorphous carbon film deposition process. A partial clean process typically includes injecting a remote plasma gas (e.g., O₂ plasma gas) directly into the process chamber above a hub. The hub is located in a center of the process chamber between four surrounding processing stations. The hub is in a default (or stowed) position during the partial clean process. The remote plasma gas is directed at a top center of the hub and then changes from flowing in a vertical direction to flowing in a horizontal (or lateral) direction across substrate supports towards corners of the process chamber. The hub includes clamps for holding transfer paddles. In the default position, the transfer paddles are located between the substrate supports.

Trenches exist between adjacent pairs of the clamps of the hub. The trenches cause concentrated and directional flow of remote plasma gas across the substrate supports and at the corners of the process chamber. This results in the corners, which are the most remote portions of the chamber, being cleaned better than other areas within the chamber. Certain areas within the process chamber receive a low percentage of remote plasma gas flow and thus are poorly cleaned due to a low cleaning efficiency occurring in these areas. The portion of the process chamber to which remote plasma gas is not directed ends up not being sufficiently cleaned. The poorly cleaned areas have carbon residue remaining at the end of the partial clean process. Carbon residue can remain, for example, on the chamber ribs, side interior walls, slit valves, etc. The slit valves include doors through with substrates are transferred in and out of the process chamber. The partial clean process cannot thoroughly clean the process chamber in a time efficient manner, and is limited in process throughput.

The examples set forth herein include multi-stepped hub positioning for providing directional remote plasma gas flow (or clean radical gas flow) at different angles to more efficiently and better clean areas within a process chamber. During an enhanced partial clean process, the hub is rotated one or more times to change directional flow of remote plasma gas. This allows additional areas to be adequately cleaned during a partial clean process. For example, a hub may be rotated to 0°, 30°, 45°, 60° and/or other angles to provide efficient cleaning of remote areas including corners, sidewalls, chamber ribs, etc. The enhanced partial clean process reduces particle count within a process chamber and reduces overall clean time for increased productivity. The examples disclosed herein are applicable to low temperature processes where deposition in remote chamber areas is more significant and to other higher temperature processes. The disclosed examples may be utilized to thoroughly clean a process chamber after deposition processes and/or non-deposition processes (e.g., etch processes).

The partial clean processes disclosed herein are applicable to low temperature PECVD amorphous carbon processes, other carbon film deposition processes, and other processes during which deposits are left on components of a processing chamber. The partial clean processes improve clean efficiencies and therefore reduce clean times. The clean times can be reduced by over 50% as compared to a partial clean that includes maintaining a hub in a fixed default position throughout a cleaning process. Maintaining a hub in a fixed default position throughout a cleaning process requires a long clean time to achieve an acceptable level of chamber cleanliness.

The examples disclosed herein include multi-step remote plasma clean operations with different spindle and hub clean angles to achieve a more thorough clean of the interior of a process chamber. Remote plasma clean gas is supplied from a remote plasma source and directed at the hub via a channel and/or port of the processing chamber. The remote plasma clean gas refers to plasma gas that is generated remote from processing stations of the process chamber and supplied via a centrally located port between the processing stations for cleaning purposes. The remote plasma clean gas is supplied for cleaning components of the processing chamber including removal of deposits on the components. The multi-step remote plasma clean operations include rotating the spindle to different angle positions, maintaining the spindle at the different angle positions for set respective periods of time, and directing radical gas flow in different directions within the process chamber to achieve a more thorough and efficient clean. Rather than a fixed spindle angle to have only fixed clean directions corresponding respectively to flow directions of trenches of the hub. The operations include multiple steps in which the spindle is set to different angles. In an embodiment, the hub is iteratively rotated in a stepped or incremental manner such that radical flow is directed to “swipe” an entire process chamber to achieve a more efficient and thorough clean. With the increased cleaning efficiency, clean time is reduced while achieving a good clean result (e.g., number of particles per unit area is less than or equal to a target number of particles per unit area).

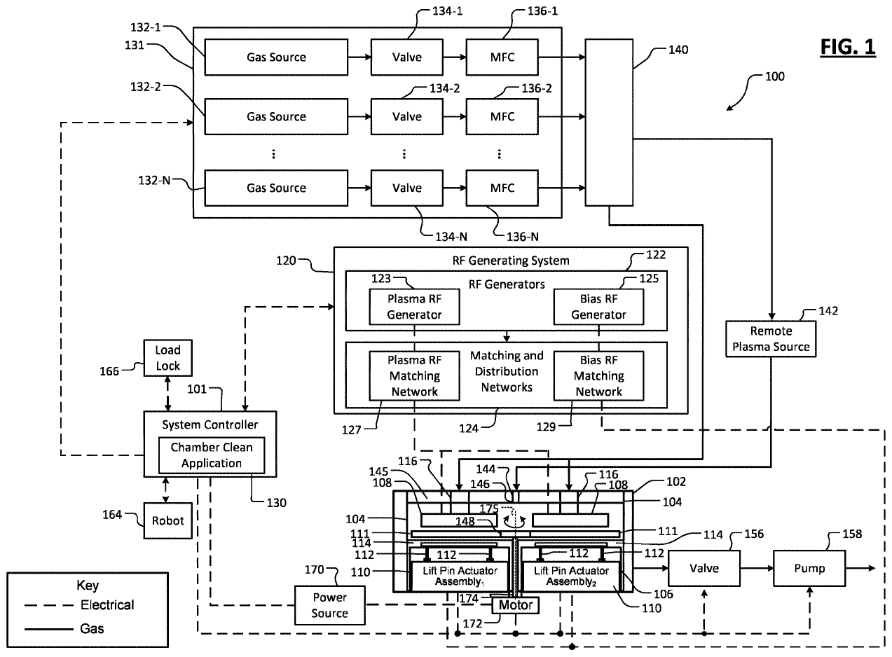

FIG. 1 shows a portion 100 of a substrate processing system (or tool) including a system controller 101 implementing chamber clean processes as disclosed herein. The chamber clean processes include a full clean process and a partial clean process. The partial clean process includes cleaning components within a process chamber including removal of deposits on the components. The partial clean process may be performed subsequent to each deposition process performed. The full clean process includes one or more iterations of the partial clean process and also includes removal of an undercoat layer. These processes are further described below. Each process may include multi-step positioning of spindle and hub for efficient cleaning of inner chamber elements post carbon film layer deposition.

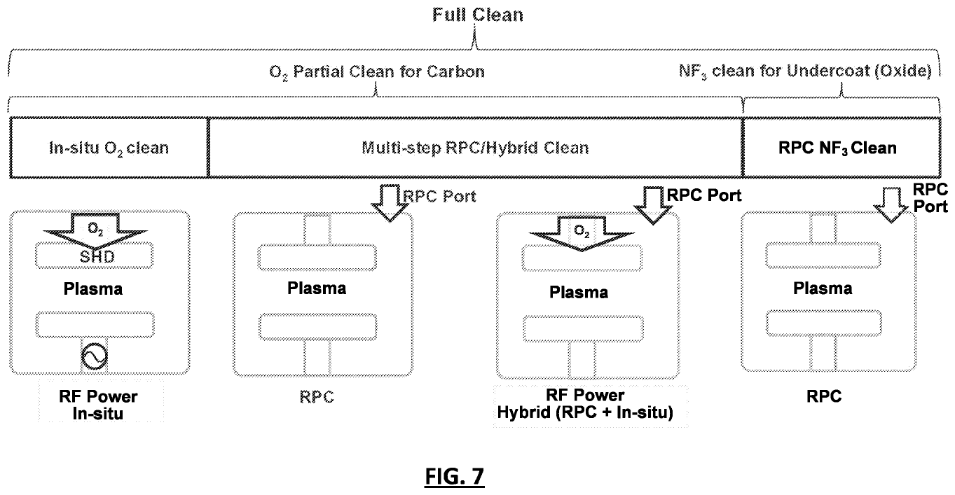

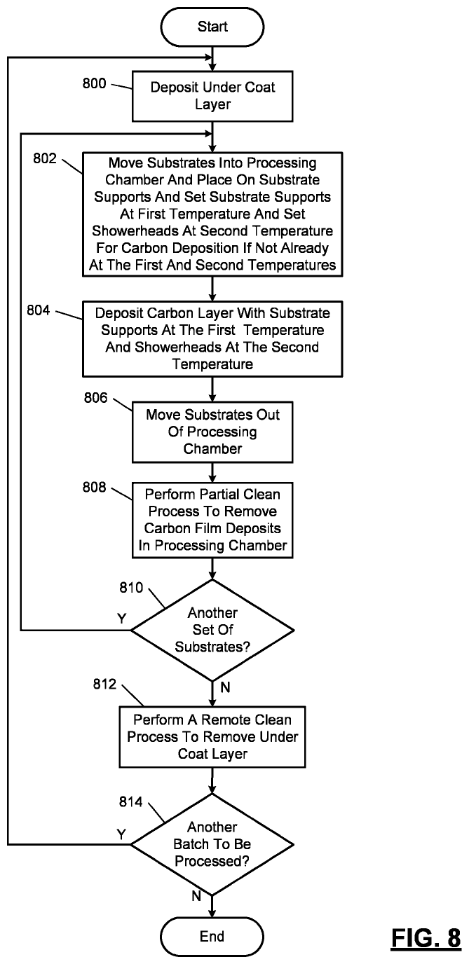

The full clean process is performed after processing a batch of substrates to remove undercoat layers. The undercoat layers are deposited on the substrate supports prior to processing the batch of substrates. A “batch” refers to a predetermined number of carbon film layer deposition processes, where each carbon film layer deposition process includes depositing a carbon film layer on each of multiple substrates. For example, a process chamber may include four stations having respective substrates. During a single carbon film layer deposition process, a carbon film layer is deposited on each of the four substrates. Example full clean processes are described below with respect to FIGS. 7 and 8.

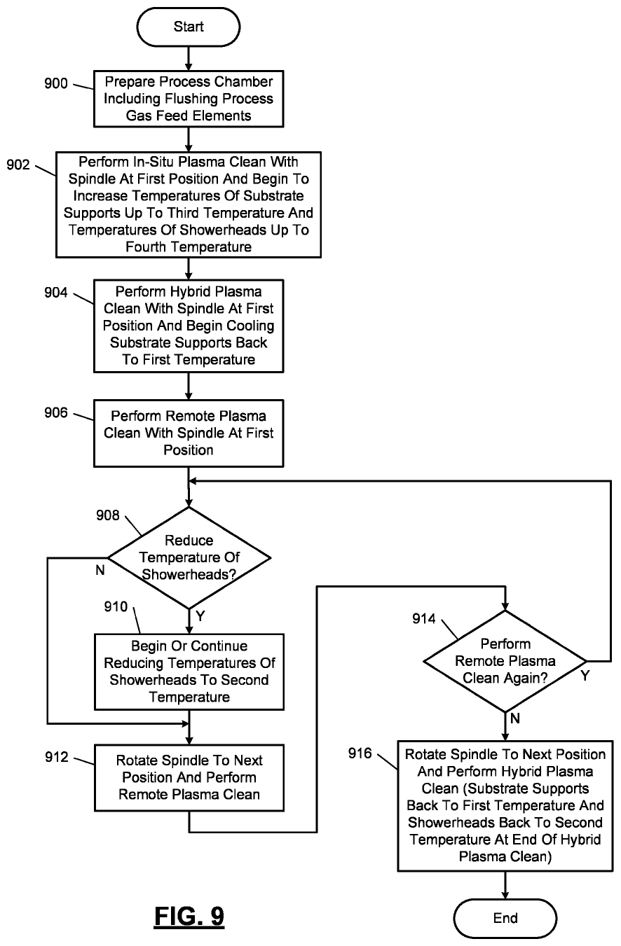

A partial clean process is performed as part of each carbon film layer deposition process and after each carbon film layer deposition operation. Each carbon film layer deposition operation includes depositing a carbon film layer on each substrate in the process chamber. Example partial clean processes are described below with respect to FIGS. 7 and 9.

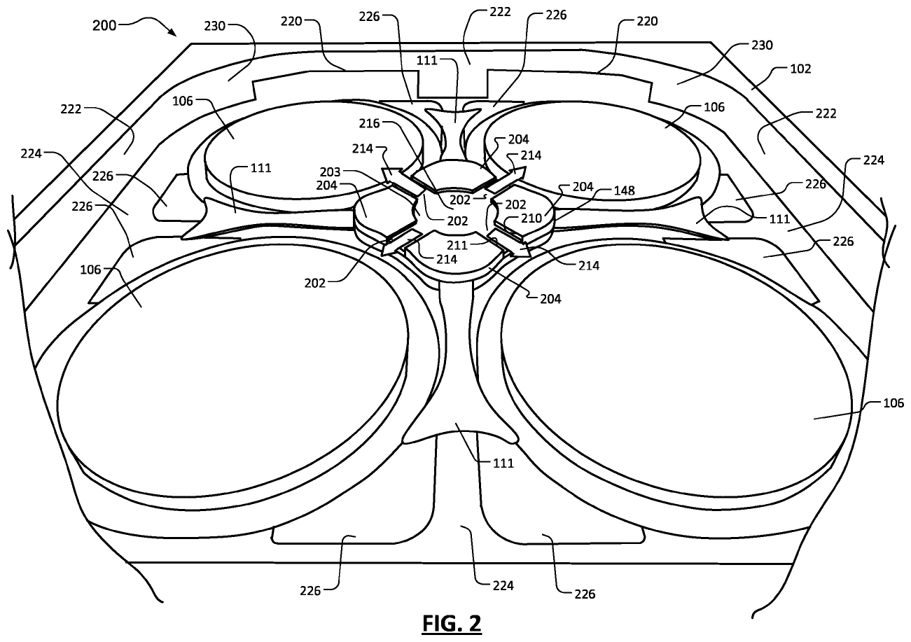

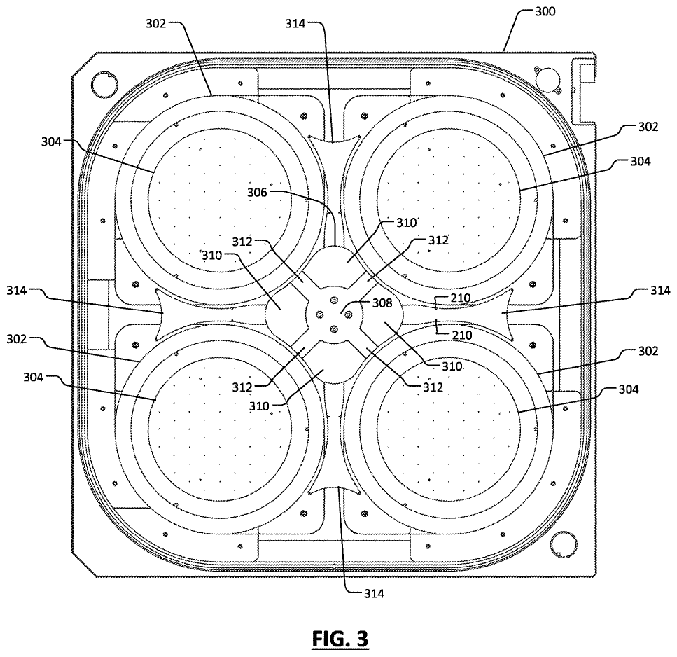

The substrate processing system includes a process chamber 102 having multiple processing stations 104, two processing stations are shown in FIG. 1, however, the process chamber 102 may have four processing stations as shown in FIGS. 2-3. In one embodiment, each of the processing stations 104 may be used to implement a carbon film deposition process for a respective substrate.

Each of the processing stations 104 includes respective substrate supports (e.g., substrate supports 106), such as electrostatic chucks, and showerheads (e.g., showerheads 108). The substrate supports may be referred to as pedestals. The substrate supports may include respective lift pin actuator assemblies (e.g., lift pin actuator assemblies 110). The lift pin actuator assemblies include lift pins (e.g., lift pins 112) that are actuated to lift substrates (e.g., substrates 114) on and off of the substrate supports and substrate transfer paddles 111.

Each of the processing stations 104 includes upper and lower electrodes. The showerheads may be implemented as or include the upper electrodes. The substrate supports may be implemented as or include the lower electrodes. The upper and lower electrodes may be implemented as radio frequency (RF) electrodes, bias electrodes, clamping electrodes and/or heating electrodes. For example, the upper electrodes may be implemented as the showerheads, which introduce and distributes gases in the processing stations. The showerheads may include stem portions 116 including ends connected to top surfaces of the process chamber 102. The showerheads are generally cylindrical and extend radially outward from opposite ends of the stem portions 116 at a location that is spaced from the top surface of the process chamber. Substrate-facing surfaces of the showerheads include holes through which process or purge gas flows. Alternately, the showerheads may include a conducting plate and the gases may be introduced in another manner.

An RF generating system 120 generates and outputs RF voltages to the upper electrodes and the lower electrodes. For each of the processing stations, one of the upper electrodes and the lower electrodes may be direct current (DC) grounded, alternating current (AC) grounded or at a floating potential. For example, the RF generating system 120 may be controlled by the system controller 101 and include one or more RF generators 122 (e.g., a capacitive coupled plasma RF power generator, a bias power generator, and/or other RF power generator) that generate RF voltages, which are fed by one or more matching and distribution networks 124 to the upper electrodes and/or the lower electrodes. The system controller 101 sets and adjusts frequencies of RF signals output from the RF generators 123, 125. The frequencies may be adjusted to adjust power distribution within and across the substrate supports. The system controller 101 may be connected to and/or include memory, which may store a chamber clean application 130 for implementing cleaning processes disclosed herein.

As an example, a first RF generator 123, a second RF generator 125, a first RF matching network 127 and a second RF matching network 129 are shown. The first RF generator 123 and the first RF matching network 127 may provide a RF voltage or may simply connect the showerheads to a ground reference. The second RF generator 125 and the second RF matching network 129 may each or collectively be referred to as a power source and provide a RF/bias voltage to the substrate supports. In one embodiment, the first RF generator 123 and the first RF matching network 127 provides power that ionizes gas and drives plasma. In another embodiment, the second RF generator 125 and the second RF matching network 129 provide power that ionizes gas and drives plasma. One of the RF generators 123, 125 may be a high-power RF generator producing, for example 6-10 kilo-watts (KW) of power or more.

A gas delivery system 131 includes one or more gas sources 132-1, 132-2, . . . , and 132-N (collectively gas sources 132), where N is an integer greater than zero. The gas sources 132 supply one or more precursors and gas mixtures thereof. The gas sources 132 may also supply etch gas, carrier gas and/or purge gas. The gas sources 132 are connected by valves 134-1, 134-2, . . . , and 134-N (collectively valves 134) and mass flow controllers 136-1, 136-2, . . . , and 136-N (collectively mass flow controllers 136) to a manifold and valve assembly 140. An output of the manifold and valve assembly 140 is fed to the process chamber 102. For example, the output of the manifold and valve assembly 140 is fed to the showerheads.

The manifold and valve assembly 140 may also supply gases to a remote plasma source 142. The remote plasma source 142 may supply, for example, oxygen (O₂) plasma to a center channel 144 in a center top plate 145 and out an output port 146 to a center of the process chamber 102. The O₂ plasma is directed to a center of a hub 148 for chamber cleaning purposes, as further described below. The output port 146 is located above and in lateral alignment with a center of the hub 148.

A valve 156 and pump 158 may be used to evacuate reactants from the process chamber 102. The system controller 101 may control components of the substrate processing system including controlling supplied RF power levels, pressures and flow rates of supplied gases, RF matching, etc. The system controller 101 controls states of the valve 156 and the pump 158. A robot 164 may be used to deliver substrates into and remove substrates from the processing stations 104. For example, the robot 164 may transfer substrates between the substrate supports 106 and a load lock 166. The robot 164 may be controlled by the system controller 101. The system controller 101 may control operation of the load lock 166. The valves, gas and/or coolant pumps, power sources, RF generators, etc. may be referred to as actuators.

The substrate processing system further includes a power source 170 that may supply power to the system controller 101, the lift pin actuator assemblies 110 and a motor 172. The motor 172 rotates a spindle 174. The power source 170 may be controlled by the system controller 101. The system controller 101 may control supply of power from the power source 170 to the motor 172 and/or to the RF generating system 120. The motor 172 may be used to rotate the spindle during cleaning processes to different positions for cleaning different areas within the process chamber 102.

The lift pin actuator assemblies 110 raise and lower the lift pins 112. The lift pin actuator assemblies 110 may include electrical and/or pneumatic actuators for adjusting positions of the lift pins 112. The motor 172 rotates a spindle 174, which is connected to and thus rotates the hub 148 about a vertical center axis 175. The hub 148 is connected to hub portions of the substrate transfer paddles 111. The hub portions may be held by the hub 148 using clamps. The substrate transfer paddles 111 may extend laterally and/or horizontally from the hub 148. Top and/or bottom planar surfaces of the substrate transfer paddles 111 may be parallel to top and/or bottom planar surfaces of the substrate supports 106.

During operation, the substrate transfer paddles 111 are rotated to position the substrates 114 over the substrate supports 106. The lift pins 112 are raised to lift the substrates 114 off the substrate transfer paddles 111 and the substrate transfer paddles 111 are rotated out of the way to stowed positions. The lift pins 112 are then lowered to set the substrates 114 on the substrate supports 106. One or more processing operations (e.g., etch, deposition, or clean operation) are then performed on the substrates 114. Subsequently, the lift pins 112 are raised to lift the substrates off of the substrate supports 106 and the substrate transfer paddles 111 are rotated to be between the substrate supports 106 and the substrates 114. The lift pins 112 are then lowered to set the substrates 114 back on the substrate transfer paddles 111. This process may be repeated and the substrates may be moved from processing station to processing station in this manner. Each processing station may perform a different set of processing operations.

The lift pins 112 may also be used to allow delivery and removal of the substrates 114 from the process chamber 102 using a robot arm of the robot 164. Upper ends of the lift pins 112 may be located flush with or below upper surfaces of the substrate supports 106 when stowed. During substrate delivery, removal and/or transfer, the lift pins are raised relative to the upper surfaces of the substrate supports 106 to lift the substrates 114 and provide clearance between the substrates 114 and the substrate supports 106. The clearance between the substrates 114 and the substrate supports 106 allows (i) an end effector of the robot arm to be inserted or removed, and (ii) the substrate transfer paddles to be moved between the substrates 114 and the substrate supports 106.

FIG. 2 shows an interior 200 of the process chamber 102 including the hub 148 with directional trenches 202. The hub 148 includes a cover 203 and clamps 204 that hold the substrate transfer paddles 111. The substrate transfer paddles 111 are equally distanced apart from each other about the hub 148. The substrate transfer paddles 111 are 90° apart from each other. The directional trenches 202 direct remote plasma cleaning gas (e.g., O2 plasma gas) at 45° angles relative to the substrate transfer paddles 111. Each of the directional trenches 202 is defined by i) portions of sides of an adjacent pair the clamps 204, and ii) a portion of a top surface of the cover 203 disposed between the portions of the sides of the adjacent pair of clamps 204. Examples portions of one of the directional trenches 202 are designated 210, 211. The portions protrude upward from the top surface of the cover 203. Directional flow of the remote plasma gas is represented by arrows 214. Remote plasma gas is provided during cleaning operations and directed vertically down towards a center 216 of the hub 148. The remote plasma gas is then directed laterally across the substrate supports 106 as shown by arrows 214.

The process chamber 102 further includes the substrate supports 106. The substrate transfer paddles 111 are shown in a stowed 0° position. In this position, the substrate transfer paddles 111 are located between the substrate supports 106. Substrates are provided through slit valve openings 220 and placed on the substrate supports 106. Chamber ribs 224 are shown and extend from side walls 222, between inserts 226, and inward below the substrate transfer paddles 111.

The hub 148 is rotated to direct remote plasma gas at different angles across the substrate supports 106. This allows various areas within the process chamber 102 to be cleaned including the side walls 222, the chamber ribs 224, slit valve doors in the slit valve openings 220, the corners 230, and other areas and interior chamber elements within the process chamber 102.

Partial cleaning to remove carbon deposits may include using oxygen radicals in carrier gas from the remote plasma source 142 of FIG. 1 through the port 146 at the center and at the center 216. A large portion of the radical flow hits the top of the hub 148 and then is directed by the directional trenches 202 (or grooves). As a result, the process chamber 102 is cleaned efficiently in flow directions of the directional trenches 202. The hub 148 is rotated such that the flow directions change for each rotated position of the hub 148, which allows various areas within the process chamber 102 to be cleaned efficiently.

FIG. 3 shows a process chamber 300 that may be configured similarly as the process chamber 102 of FIGS. 1-2. The process chamber 300 includes processing stations 302 with substrate supports 304 and a hub 306 with a cover 308, clamps 310 and trenches 312. The clamps 310 hold substrate transfer paddles 314. The process chamber 300 is shown with the substrate transfer paddles 314 in a stowed state but may be rotated over substrate supports 304 to a deployed state.

The substrate transfer paddles 314 are held by and extend from the hub 306. In the stowed state, the substrate transfer paddles 314 are disposed between the processing stations 302. When deployed, the substrate transfer paddles 314 are disposed in locations between the stowed positions. During or between processing operations, the hub 306 may be rotated to move the substrate transfer paddles 314 from current processing stations to stowed positions and then from the stowed positions to next processing stations in a clockwise or counterclockwise directions. During cleaning, the hub 306 may be rotated to direct remote plasma clean gas to different remote regions within the interior of the process chamber 300. The hub 306 may be rotated in clockwise or counterclockwise directions.

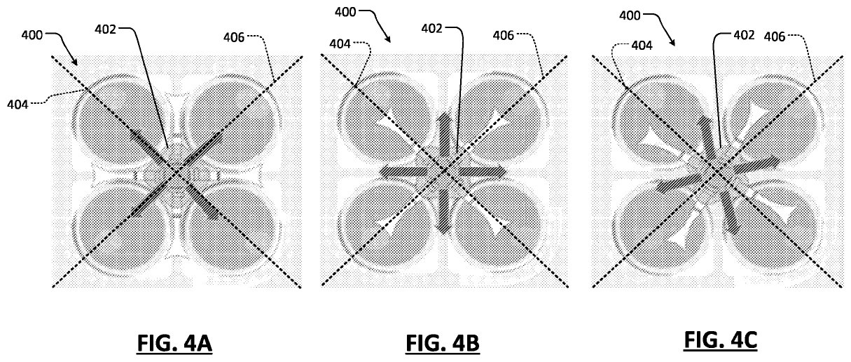

FIG. 4A shows a process chamber 400 illustrating a hub 402 in a first (or default) position. Flow direction of remote plasma clean gas is at an angle of 0° relative to axes 404, 406 extending through corners of the process chamber 400 and directed at the corners. FIG. 4B shows the process chamber 400 illustrating the hub 402 in a second position. Flow direction of remote plasma clean gas is at an angle of 45° relative to axes 404, 406 and directed at side walls of the process chamber 400. FIG. 4C shows the process chamber 400 illustrating the hub 402 in a third position. Flow direction of remote plasma clean gas is at an angle of 30° or 60° relative to axes 404, 406 depending on direction of rotation of the hub 402 and which direction (clockwise or counterclockwise) is a positive angular rotation.

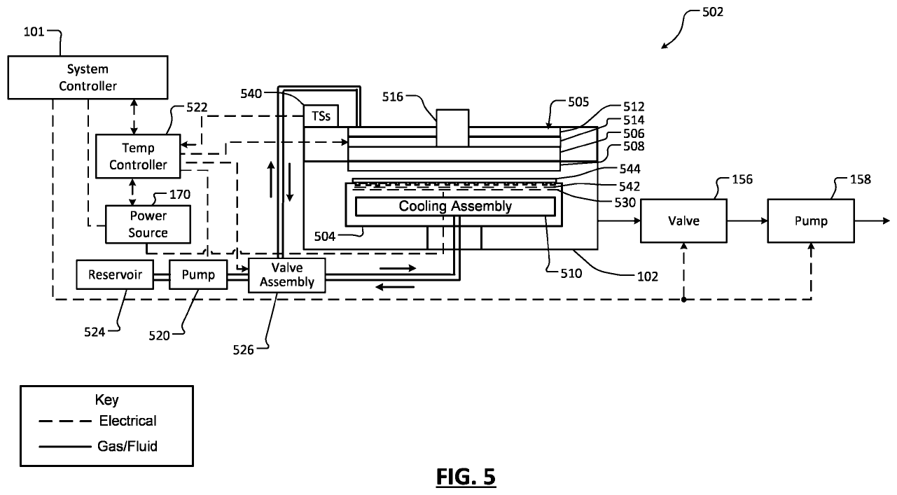

FIG. 5 shows another portion 500 of the substrate processing system of FIG. 1 including a temperature control system 502 for heating and cooling substrate supports and showerheads during cleaning processes. In the example shown, a single substrate support 504 and a single showerhead assembly 505 are shown. The showerhead assembly 505 may include a gas distribution plate 506 and a faceplate 508, which collectively provide a showerhead. A similar configuration may be provided for other substrate supports and showerhead assemblies of the substrate processing system.

The substrate support 504 includes a cooling assembly 510 and the showerhead assembly 505 includes a cold (or cooling) plate 512 and a heating plate 514. A stem 516 may extend through the plates 506, 512, 514 and supply process gas to the gas distribution plate 506, which distributes the process gas via the showerhead faceplate 508. The gas distribution plate 506 and the showerhead faceplate 508 are collectively cylindrical-shaped and extend radially outward at a location that is at an opposite end of the stem 516 as a top surface of the process chamber 102. A substrate-facing surface of the showerhead faceplate 508 includes holes through which process or purge gas flows. The heat plate 514 may be disposed on the gas distribution plate 506. The cold plate 512 may be disposed on the heat plate 514. The cooling assembly 510 and/or the cold plate 512 may receive coolant from a pump 520 and include coolant channels for circulating coolant.

A temperature controller 522 may control operation of the pump 520 to control flow and temperature of coolant to and from the cooling assembly 510 and the cold plate 512. The pump 520 may circulate coolant between i) a reservoir 524 and ii) the cooling assembly 510 and the cold plate 512. Although a single pump 520 is shown, two or more pumps may be included. In one embodiment, each of the cooling assembly 510 and the cold plate 512 includes a single coolant input and a single coolant output. In other embodiments, each of the cooling assembly 510 and the cold plate 512 includes multiple coolant inputs and coolant outputs. A valve assembly 526 may be disposed between the pump 520 and the cooling assembly 510 and the cold plate 512 and be controlled by the temperature controller 522. Pairs of supply and return lines may be connected (i) between the one or more pumps and the cooling assembly 510 and the cold plate 512, and/or (ii) between the valve assembly 526 and the cooling assembly 510 and the cold plate 512.

The RF generating system 120 of FIG. 1 generates and outputs RF voltages to the upper electrode (or showerhead) and one or more lower electrodes 530 in the substrate support 504. One of the upper electrode and the substrate support 504 may be DC grounded, AC grounded or at a floating potential. For example only, the RF generating system 120 may generate RF voltages, which are fed by one or more matching and distribution networks 124 of FIG. 1 to the upper electrode and/or the substrate support 504.

Although shown separately from the system controller 101, the temperature controller 522 may be implemented as part of the system controller 101. The substrate support 504, the cooling assembly 510, the gas distribution plate 506, and/or the cold plate 512 may include multiple temperature controlled zones, where each of the zones includes a temperature sensor and a set of channels. The temperature controller 522 may monitor temperatures as indicated by the temperature sensors and adjust flow rate and/or temperature of coolant circulating through the one or more sets of channels to adjust the temperatures to target temperatures. The temperatures sensors and other temperatures sensors are represented by temperature sensors 540. Although the temperature sensors 540 are shown as being connected to the process chamber 102, at least some of the temperature sensors 540 are located within the process chamber 102. The temperature sensors 540 may include resistive temperature devices, thermocouples, digital temperature sensors, and/or other suitable temperature sensors.

The substrate processing system may include the power source 170 that provides power, including a high voltage, to clamping electrodes 542 to electrostatically clamp a substrate 544 to the substrate support 504. Clamping electrodes receive power to electrostatically clamp down the substrate 544 to the substrate support 504 and may receive RF signals, RF voltages and/or RF power. The power source 170 may be controlled by the system controller 101.

The temperature controller 522 may control operation of the pump 520 and/or other coolant circulating pumps and/or the valve assembly 526 based on detected parameters from the temperature sensors 540, which may be within the process chamber 102. The valve 156 and the pump 158 may be used to evacuate reactants from the process chamber 102. The system controller 101 controls states of the valve 156 and the pump 158.

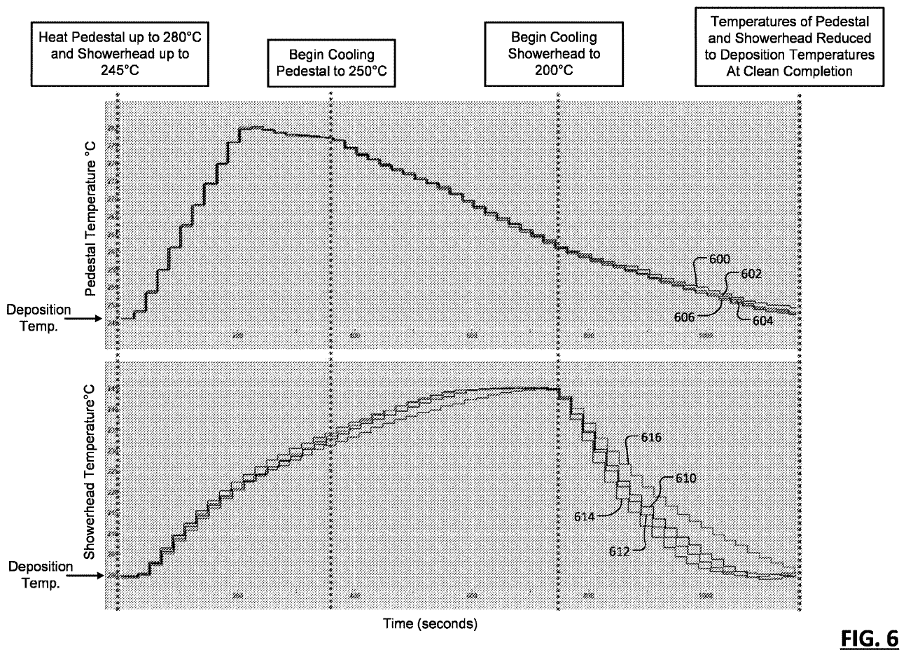

FIG. 6 shows a plot of substrate support (or pedestal) and showerhead temperatures during a partial clean process. Curves 600, 602, 604, 606 are pedestal temperatures respectively of four pedestals in a process chamber. Curves 610, 612, 614, 616 are showerhead temperatures of respectively four showerheads in the process chamber. The showerheads are arranged respectively above the pedestals. During an embodiment, temperatures of the pedestals and the showerheads are first increased and then decreased to improve cleaning efficiency of remote plasma gas (e.g., O₂ plasma gas). At the beginning of a partial clean, pedestal temperatures are increased from first (or deposition) temperatures to second temperatures and showerhead temperatures are increased from third (or deposition) temperatures to fourth temperatures. As an example, the temperatures of the pedestals may be increased from 250° C. to 280° C. and the temperatures of the showerheads may be increased from 200° C. to 245° C. During the partial clean process, the temperatures are reduced back down to the deposition temperatures such that at the end of the partial clean process the pedestals and showerheads are back down to the deposition temperatures, as shown by the plots. In an embodiment, the temperatures of the pedestals are reduced prior to reducing the temperatures of the showerheads.

FIG. 7 shows a cleaning diagram illustrating a full clean process. The full clean process includes i) performing a partial clean process to remove carbon deposits within a process chamber, and ii) performing a remote plasma clean process to remove an undercoat layer. A partial clean may be performed after deposition of a carbon film layer and is used to remove carbon deposits within a process chamber, as further described below with respect to FIGS. 8-9. A remote plasma clean process to remove an undercoat layer may be performed after processing each batch of substrates to remove an undercoat layer (or undercoat deposits) within the process chamber, as further described below with respect to FIG. 8. A batch may refer to a predetermined number of sets of substates, where each set of substrates includes, for example, four substrates for a process chamber having four pedestals.

The partial clean process may include i) one or more in-situ clean operations, ii) one or more remote plasma clean operations without RF power, and iii) one or more hybrid clean operations including both in-situ and remote plasma clean operations. An in-situ clean operation may include introducing gas via showerheads into the process chamber and providing RF power via the showerheads and/or pedestals to generate local plasma gas to clean at least local areas within the process chamber. As an example, the gas may be O₂ gas, and the local plasma gas may be O₂ plasma gas. A remote plasma clean operation may include introducing remote plasma gas via a port (e.g., port 146 of FIG. 1) centrally located between processing stations. As an example, the remote plasma gas may be O₂ plasma gas. A hybrid clean operation may include concurrently performing an in-situ (or local) clean operation and a remote plasma clean operation. The remote plasma clean operations and the hybrid clean operations may be part of a multi-step remote plasma and hybrid clean process. This process may be performed subsequent to performing one or more in-situ clean operations.

The remote plasma clean process to remove the undercoat layer may be performed subsequent to performing the multi-step remote plasma and hybrid clean process. As an example, the undercoat layer may be a silicon oxide (SiO₂) layer. The remote plasma clean process to remove the undercoat layer may include as an example introducing remote plasma clean gas, such as nitrogen fluoride (NF₃) via a port (e.g., the port 146 of FIGS. 1-2).

During the remote plasma clean processes to remove carbon deposits, the hybrid clean processes, and/or the remote plasma clean processes to remove undercoat deposits, a hub (e.g., the hub 148 of FIG. 1 or hub 306 of FIG. 3) may be rotated to multiple different positions to direct plasma gas in different directions to clean different areas within the corresponding process chamber. The hub may be maintained at each of the positions a predetermined amount of time. As an example, the hub may be at each of the positions a same amount of time. As another example, the hub may be at each of the positions a different amount of time. In one embodiment, the partial clean process includes rotating the hub to four positions including 0°, 30°, 45°, and 60° positions. As an example, the hub is in the 0° position for a first period of time (e.g., 3.5 minutes), the 45° position a second period of time (e.g., 2.5 minutes), and in each of the 30° and 60° positions a third period of time (e.g., 5 minutes). Other examples are provided below.

FIG. 8 shows a carbon deposition process including a full clean process. The processes may be performed by the substrate processing system of FIGS. 1 and 5. The following operations may be iteratively performed. The operations may be performed by the system controller 101 of FIGS. 1 and 5. At 800, an undercoat layer is deposited on substrate supports. The undercoat layer may include silicon oxide (SiO₂).

At 802, substrates are moved into the process chamber and placed on the substrate supports. The substrate supports are set at a first temperature and the showerheads are set at a second temperature for carbon deposition. The first temperature may be 250° C. and the second temperature may be 200° C. The first and second temperatures may be referred to as deposition temperatures.

At 804, a carbon layer is deposited on the substrates with the substrate supports at the first temperature and the showerheads at the second temperature. Acetylene (C₂H₂) and helium are introduced via the showerheads. Acetylene has a low molecular weight and is diffusive. In an embodiment, PECVD carbon deposition is performed to deposit PECVD amorphous carbon film layer on the substrates to form ashable hard mask layer on the substrates. As an example, the PECVD amorphous carbon film layer may be 2 microns (u) thick. Pressure within the process chamber may be at less than 1 Torr. Subsequent to carbon deposition, the substrates are moved out of the process chamber at 806.

At 808, a partial clean process is performed to remove carbon film deposits in the process chamber. At 808, the method of FIG. 9 may be performed.

At 810, the system controller 101 may determine whether carbon film layers are to be deposited on another set of substrates. If yes, operation 802 is performed, otherwise operation 812 is performed.

At 812, the system controller 101 performs a remote clean process to remove undercoat layers on parts within the process chamber. This process may include rotating the hub 148 to multiple positions to direct remote plasma gas to different areas within the process chamber 102. The hub 148 may be rotated to any number of positions and held at each of the positions for predetermined periods of time. In one embodiment, the hub 148 is positioned in 2-5 positions. In an embodiment, the hub 148 is positioned in five positions and the positions are 0°, 30°, 45°, 60° and 90° positions.

At 814, the system controller 101 determines whether another batch is to be processed. If yes, operation 800 is performed, otherwise the method may end.

FIG. 9. shows a partial clean process. Although the process is described as having a certain number of in-situ, remote, and hybrid cleaning operations with the hub 148 at a certain number of positions for each of these operations, any number of in-situ, remote and hybrid clean operations may be performed. The operations may be performed by the system controller 101 of FIGS. 1 and 5. At 900, the process chamber 102 is prepared, which includes flushing gas feed elements with nitrogen gas to remove any residue in the gas feed elements. The gas feed elements may include gas lines, gas ports, gas valves, mass flow controllers, etc.

At 902, an in-situ plasma clean operation is performed with the spindle 174 and the hub 148 in a first position (e.g., 0° position) to remove carbon deposits. The system controller 101 increases temperatures of the substrate supports up to a third temperature and increases temperatures of the showerheads up to a fourth temperature. The third temperature is higher than the first temperature. As an example, the third temperature may be 280° C. The fourth temperature is higher than the second temperature. As an example, the fourth temperature may be 245° C.

At 904, the system controller 101 performs a hybrid plasma clean operation including an in-situ plasma clean operation and concurrently a remote plasma clean operation remove carbon deposits. The spindle 174 and hub 148 are maintained at the first position (e.g., 0° position). As an example, O₂ gas may be supplied via showerheads for the in-situ plasma clean operation and O₂ plasma gas may be supplied from the remote plasma source 142 for the remote plasma clean operation. For the in-situ plasma clean, RF power may be supplied via the showerheads and/or substrate supports to generate O₂ plasma gas. For the remote plasma clean operation, a carrier gas (e.g., nitrogen) may be used to transport O₂ plasma gas into the process chamber via the port 146.

At 906, the system controller 101 performs a remote plasma clean operation while maintaining the spindle 174 and the hub 148 at first position (e.g., 0° position). As an example, a remote O₂ plasma gas may be introduced during remote plasma clean operation. This operation may include introduction of oxygen, nitrogen and argon gas. For the remote plasma clean operation, a carrier gas (e.g., nitrogen) may be used to transport O₂ plasma gas from the remote plasma source 142 into the process chamber via the port 146.

At 908, the system controller 101 determines whether to reduce temperature of the showerheads. If yes operation 910 is performed, otherwise operation 912 is performed. At 910, the system controller 101 begins reducing temperatures of the showerheads such that at the end of the partial clean process, the showerheads are back down to the showerhead deposition temperature (or second temperature). The showerhead deposition temperature may be 200° C. In one embodiment, the reduction in the temperatures of the showerheads begins when the spindle 174 and the hub 148 are rotated to the 45° position.

At 912, the system controller 101 rotates the spindle 174 and hub 148 to next position and performs remote plasma clean. As an example, the next position may be a 30° position, a 45° position, a 60° position, or another position. In one embodiment, when the spindle 174 and the hub 148 are positioned in a total of two positions, the next position is the 45° position. In another embodiment, when the spindle 174 and the hub 148 are positioned in a total of 3-5 positions, the next position is the 30° position or a 60° position. As an example, operation 908 may be performed three times, where the next position is the 30° position, followed by the 45° position, and then followed by the 60° position.

At 914, the system controller 101 determines whether to perform remote plasma clean again. If yes, operation 908 is performed, otherwise operation 916 is performed.

At 916, the system controller 101 rotates the spindle 174 and the hub 148 to a next position and performs a hybrid plasma clean process including an in-situ plasma clean and a remote plasma clean. As an example, the in-situ plasma clean may include supplying O₂ gas via the showerheads. For the in-situ clean, RF power is supplied via the showerheads and/or substrate supports to generate O₂ plasma gas between the showerheads and the substrate supports. For the remote plasma clean, a carrier gas (e.g., nitrogen) may be used to transport O₂ plasma gas from the remote plasma source 142 into the process chamber via the port 146.

As an example, the next position may be a 90° position. At the end of the hybrid clean process, the substrates supports are back down to the substrate support deposition temperature (e.g., 250° C.) and the showerheads are back down to the showerhead deposition temperature (e.g., 200° C.). The method may end after operation 916. Operation 810 may be performed subsequent to operation 916.

The above-described operations of FIGS. 8-9 are meant to be illustrative examples. The operations may be performed sequentially, synchronously, simultaneously, continuously, during overlapping time periods or in a different order depending upon the application. Also, any of the operations may not be performed or skipped depending on the implementation and/or sequence of events.

The examples disclosed enhance remote plasma clean efficiency for low temperature thick PECVD amorphous carbon deposition processes, and thus reduce the clean time and cost associated with performing carbon film layer deposition. The example includes incorporating and proliferating the enhanced chamber clean operations to a multi-step remote and hybrid plasma clean operations. This includes providing clean radical flow which is intentionally directed in different directions. The clean radical flow may be swiped over the interior of a process chamber which improves clean efficiency and effectiveness. The examples reduce the remote plasma clean time, as compared to a remote plasma clean process where a spindle and hub are held in a fixed position, by over 50% while also satisfying cleaning requirements.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Although the terms first, second, third, etc. may be used herein to describe various elements, parameters, components, and/or devices, these elements, parameters, components, and/or devices should not be limited by these terms, unless otherwise indicated. These terms may be only used to distinguish one element, parameter, component, or device from another element, component, or device. Terms such as “first,” “second,” and other numerical terms when used herein do not imply a sequence or order unless clearly indicated by the context. Thus, a first element, parameter, component, or device could be termed a second element, parameter, component, or device without departing from the teachings of the example embodiments.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system comprising:
a process chamber;
a plurality of processing stations disposed in the process chamber, each of the plurality of processing stations comprising a respective substrate support; and
a hub disposed between the plurality of processing stations, the hub to rotate between a first position and a second position, to direct a gas to clean a first area of the process chamber when in the first position, and to direct the gas to clean a second area of the process chamber when in the second position.

2. The substrate processing system of claim 1, wherein each of the plurality of processing stations comprises a respective showerhead.

3. The substrate processing system of claim 1, wherein the hub is configured to hold a plurality of substrate transfer paddles for transferring substrates between the plurality of processing stations.

4. The substrate processing system of claim 1, wherein the gas is a remote plasma clean gas received from a remote plasma source.

5. The substrate processing system of claim 1, wherein the gas comprises O₂ plasma gas.

6. The substrate processing system of claim 1, wherein the hub comprises a plurality of trenches for directing the gas at areas within the process chamber.

7. The substrate processing system of claim 1, further comprising at least one controller configured to perform one or more cleaning processes to remove deposits from within the process chamber, the one or more cleaning processes comprise directing the gas at the hub and rotating the hub between the first position and the second position.

8. The substrate processing system of claim 7, wherein the at least one controller is configured to deposit a carbon film layer on each of a plurality of substrates held by the substrate supports, remove the plurality of substrates from the process chamber, and perform the one or more cleaning processes to remove carbon deposits within the process chamber.

9. The substrate processing system of claim 7, wherein the at least one controller is configured to rotate the hub to 0°, 30°, 45° and 60° positions during the one or more cleaning processes.

10. The substrate processing system of claim 7, wherein the at least one controller is configured to rotate the hub to 2-5 different positions during the one or more cleaning processes.

11. The substrate processing system of claim 7, wherein the at least one controller is configured to rotate the hub to 3-4 different positions during the one or more cleaning processes.

12. The substrate processing system of claim 7, wherein the at least one controller is configured to rotate the hub to at least 3 different positions during the one or more cleaning processes.

13. The substrate processing system of claim 7, wherein the at least one controller is configured to perform:
a first in-situ plasma clean operation;
a hybrid clean operation including performing a second in-situ plasma clean operation concurrently with performing a first remote plasma clean operation; and
a second remote plasma clean operation.

14. The substrate processing system of claim 13, wherein the at least one controller is configured to maintain the hub in a first position while performing the first in-situ plasma clean operation, the hybrid clean operation, and the second remote plasma clean operation.

15. The substrate processing system of claim 13, wherein the at least one controller is configured to, during the hybrid clean operation, decrease temperatures of the substrate supports.

16. The substrate processing system of claim 7, wherein the at least one controller is configured to i) perform an in-situ plasma clean operation, ii) increase temperatures of the substrate supports and showerheads of the plurality of processing stations for the in-situ plasma clean operation, and iii) reduce the temperatures of the substrate supports and the showerheads subsequent to performing the in-situ plasma clean operation.

17. The substrate processing system of claim 7, wherein the at least one controller is configured to:
deposit an undercoat layer on each of the substrate supports;
move a plurality of substrates onto the substrate supports;
deposit a carbon film layer on each of the substrates held by the substrate supports;
remove the substrates; and
perform a remote plasma clean operation to remove the undercoat layer from each of the substrate supports.

18. The substrate processing system of claim 17, wherein the remote plasma clean operation to remove the undercoat layer comprises introducing nitrogen fluoride gas into the process chamber and directing the nitrogen fluoride gas at a center of the hub.

19. The substrate processing system of claim 7, wherein the at least one controller is configured to maintain the hub at a plurality of different angular positions for a plurality of different periods of time during each of the one or more cleaning processes.

20. The substrate processing system of claim 7, wherein the at least one controller is configured to:
perform a first remote plasma clean operation while the hub is in the first position;
perform a second remote plasma clean operation while the hub is in the second position;
perform a third remote plasma clean operation while the hub is in a third position;
perform a fourth remote plasma clean operation while the hub is in a fourth position; and
perform a hybrid plasma clean operation while the hub is in a fifth position.

21. The substrate processing system of claim 20, wherein the at least one controller is configured to decrease temperatures of showerheads of the plurality of processing stations during the third remote plasma clean operation.

22. The substrate processing system of claim 20, wherein the at least one controller is configured to decrease temperatures of the substrate supports and showerheads of the plurality of processing stations such that, at an end of the hybrid plasma clean operation and in preparation for performing deposition, the substrate supports are at a first temperature and the showerheads are at a second temperature.

23. A method for cleaning an interior of a process chamber, the method comprising:
supplying a gas to the process chamber;
directing the gas at a hub, the hub being located between a plurality of processing stations, each processing station of the plurality of processing stations comprising a substrate support;
maintaining the hub at a first position for a first predetermined period of time to direct the gas at a first portion of an interior of the process chamber to clean the first portion of the interior; and
rotating the hub to a second position to direct the gas at a second portion of the interior to clean the second portion of the interior.

24. The method of claim 23, wherein the hub is configured to hold a plurality of substrate transfer paddles for transferring substrates between the plurality of processing stations.

25. The method of claim 23, further comprising:
depositing a carbon film layer on each of a plurality of substrates held by the substrate supports; and
removing the plurality of substrates from the process chamber,
wherein the directing of the gas at the first portion and the second portion removes carbon deposits within the process chamber, which were deposited during the deposition of the carbon film layer.

26. The method of claim 23, wherein the first position is a 0° position and other cleaning positions of the hub include a 30° position, a 45° position and a 60° position.

27. The method of claim 23, comprising rotating the hub to a total of 2-5 different positions including the first position and other positions during a cleaning process of the interior of the process chamber.

28. The method of claim 23, comprising rotating the hub to a total of 3-4 different positions including the first position and other positions during a cleaning process of the interior of the process chamber.

29. The method of claim 23, comprising rotating the hub to at least three different positions including the first position and other positions during a cleaning process of the interior of the process chamber.

30. The method of claim 23, wherein the gas is a remote plasma clean gas.

31. The method of claim 30, further comprising performing:
a first in-situ plasma clean operation including supplying another gas via a showerhead of each of the plurality of processing stations;
a hybrid clean operation including performing a second in-situ plasma clean operation concurrently with performing a first remote plasma clean operation, the second in-situ plasma clean operation includes supplying gas via the showerheads, and the first remote plasma clean operation includes supplying the remote plasma clean gas via a remote plasma source; and
a second remote plasma clean operation including supplying the remote plasma clean gas via the remote plasma source.

32. The method of claim 31, further comprising maintaining the hub in the first position while performing the first in-situ plasma clean operation, the hybrid clean operation, and the second remote plasma clean operation.

33. The method of claim 31, further comprising, during the hybrid clean operation, decreasing temperatures of the substrate supports.

34. The method of claim 31, further comprising:
performing an in-situ plasma clean operation;
increasing temperatures of the substrate supports and the showerheads for the in-situ plasma clean operation; and
reducing the temperatures of the substrate supports and the showerheads subsequent to performing the in-situ plasma clean operation.

35. The method of claim 23, further comprising:
depositing an undercoat layer on the substrate supports;
moving a plurality of substrates onto the substrate supports;
depositing a carbon film layer on each of substrates held by the substrate supports;
removing the plurality of substrates; and
performing a remote plasma clean operation to remove the undercoat layer.

36. The method of claim 35, wherein the remote plasma clean operation to remove the undercoat layer comprises introducing nitrogen fluoride into the process chamber.

37. The method of claim 36, wherein the remote plasma clean operation comprises supplying and directing O₂ plasma gas at the hub.

38. The method of claim 23, further comprising directing the gas via a plurality of trenches of the hub.

39. The method of claim 23, further comprising maintaining the hub at a plurality of different angular positions for a plurality of different periods of time during a cleaning process.

40. The method of claim 23, further comprising:
performing a first remote plasma clean operation while the hub is in the first position;
performing a second remote plasma clean operation while the hub is in a second position;
performing a third remote plasma clean operation while the hub is in a third position;
performing a fourth remote plasma clean operation while the hub is in a fourth position; and
performing a hybrid plasma clean operation while the hub is in a fifth position.

41. The method of claim 40, further comprising decreasing temperatures of showerheads of the plurality of processing stations during the third remote plasma clean operation.

42. The method of claim 40, further comprising decreasing temperatures of the substrate supports and showerheads of the plurality of processing stations such that, at an end of the hybrid plasma clean operation and in preparation for performing deposition, the substrate supports are at a first temperature and the showerheads are at a second temperature.
